(19) United States
(12) Patent Application Publication
(10) Pub. No.: US 2026/0190659 A1
(43) Pub. Date: Jul. 2, 2026

(54) DISPLAY DEVICE, METHOD OF MANUFACTURING THE SAME, AND ELECTRONIC DEVICE INCLUDING DISPLAY DEVICE

(71) Applicant: Samsung Display Co., LTD., Yongin-si (KR)

(72) Inventors: SUK-KUNG CHEI, Yongin-si (KR); TAEMIN KIM, Yongin-si (KR); JIYUN PARK, Yongin-si (KR); DONGGEUN SHIN, Yongin-si (KR); MINSEOK LEE, Yongin-si (KR); HO LIM, Yongin-si (KR)

(21) Appl. No.: 19/282,444

(22) Filed: Jul. 28, 2025

(30) Foreign Application Priority Data
Dec. 30, 2024 (KR) 10-2024-0201013

(51) Int. Cl. H10K 59/124; H10K 59/12

(52) U.S. Cl. CPC H10K 59/124; H10K 59/1201

(57) ABSTRACT

A display device includes a light-emitting element layer for displaying an image, a thin-film transistor layer configured to drive the light-emitting element layer, a substrate including a thin-film transistor layer formed on one surface thereof, having a thickness in a range of about 20 micrometers to about 50 micrometers, and including a glass material, and a protective layer disposed on another surface of the substrate. The protective layer includes at least a first compound including a polyhedral oligomeric silsesquioxane compound, a second compound including a resin, and a third compound including a conductive carbon-based compound.

This application claims priority to Korean Patent Application No. 10-2024-0201013, filed on Dec. 30, 2024, and all the benefits accruing therefrom under 35 U.S.C. § 119, the content of which in its entirety is herein incorporated by reference.

### BACKGROUND

### 1. Field

The disclosure relates to a display device, a method of manufacturing the same, and an electronic device including the display device.

### 2. Description of the Related Art

Display devices include a light-emitting element to display an image. Display devices are applied to various electronic devices such as smartphones, digital cameras, laptops, navigation devices, and televisions, and are being developed in various forms. Recently, technology development is actively underway to produce display devices that are thin but strong.

### SUMMARY

The disclosure includes a display device having a relatively small thickness and

relatively high strength, a method of manufacturing the same, and an electronic device including the display device.

In an embodiment of the disclosure, a display device includes a light-emitting element layer for displaying an image, a thin-film transistor layer configured to drive the light-emitting element layer, a substrate including a thin-film transistor layer formed on a first surface thereof, having a thickness in a range of about 20 micrometers to about 50 micrometers, and including a glass material, and a protective layer disposed on a second surface facing the first surface of the substrate. The protective layer includes at least a first compound including a polyhedral oligomeric silsesquioxane (“POSS”) compound, a second compound including a resin, and a third compound including a conductive carbon-based compound.

In an embodiment, the second surface of the substrate may include a portion on which etching is performed, and the protective layer may be directly disposed on the second surface of the substrate.

In an embodiment, the protective layer may have a pencil hardness of 3H or higher.

In an embodiment, a surface resistance of the protective layer may be 10¹² ohm per square (Ω/sq) or less.

In an embodiment, a thickness of the protective layer may be in a range of about 10 micrometers to about 30 micrometers.

In an embodiment, the second compound may include at least one material selected from a polyurethane resin, an acrylate resin, or an epoxy resin.

In an embodiment, the third compound may include at least one material selected from carbon black, graphite, graphene, carbon nanotubes, or conductive organic black.

In an embodiment, a sum of a content of the first compound and a content of the second compound may be about 45 wt % to about 75 wt % with respect to a total content of the protective layer, and a content of the third compound may be about 10 wt % to about 20 wt % with respect to the total content of the protective layer.

In an embodiment, the protective layer may further include at least one slip agent selected from the group including a fluorine-based compound and a silicone-based compound.

In an embodiment, a content of the slip agent may be about 10 wt % to about 15 wt % with respect to the total content of the protective layer.

In an embodiment, the protective layer may further include at least one curing agent among a photocurable agent and a thermal curable agent.

In an embodiment, a content of the curing agent may be about 5 wt % to about 20 wt % with respect to the total content of the protective layer.

In an embodiment of the disclosure, a method of manufacturing a display device, includes preparing a substrate including a glass material, forming, on a first surface of the substrate, a light-emitting element layer for displaying an image and a thin-film transistor layer for driving the light-emitting element layer, etching a second surface of the substrate to form a thickness of the substrate in a range of about 20 micrometers to about 50 micrometers, and forming a protective layer on the second surface of the etched substrate by screen printing. The protective layer includes at least a first compound including a POSS compound, a second compound including a resin, and a third compound including a conductive carbon-based compound.

In an embodiment, the second compound may include at least one material selected from a polyurethane resin, an acrylate resin, or an epoxy resin.

In an embodiment, the third compound may include at least one material selected from carbon black, graphite, graphene, carbon nanotubes, or conductive organic black.

In an embodiment, a sum of a content of the first compound and a content of the second compound may be about 45 wt % to about 75 wt % with respect to a total content of the protective layer, and a content of the third compound may be about 10 wt % to about 20 wt % with respect to the total content of the protective layer.

In an embodiment, the protective layer may further include at least one slip agent selected from the group including a fluorine-based compound and a silicone-based compound, and a content of the slip agent may be about 10 wt % to about 15 wt % with respect to the total content of the protective layer.

In an embodiment, the protective layer may further include at least one curing agent among a photocurable agent and a thermal curable agent, and a content of the curing agent may be about 5 wt % to about 20 wt % with respect to the total content of the protective layer.

In an embodiment of the disclosure, an electronic device includes a light-emitting element layer for displaying an image, a thin-film transistor layer configured to drive the light-emitting element layer and including a pixel circuit, a substrate including a thin-film transistor layer formed on a first surface thereof, having a thickness in a range of about 20 micrometers to about 50 micrometers, and including a glass material, and a protective layer disposed on a second surface facing the first surface of the substrate, a controller configured to apply a signal to the pixel circuit, and a power module configured to supply power to the controller. The protective layer includes a first compound including a POSS compound, a second compound including a resin, a third compound including a conductive carbon-based compound, a slip agent, and a curing agent.

In an embodiment, a sum of a content of the first compound and a content of the second compound may be about 45 wt % to about 75 wt % with respect to a total content of the protective layer, a content of the third compound may be about 10 wt % to about 20 wt % with respect to the total content of the protective layer, a content of the slip agent may be about 10 wt % to about 15 wt % with respect to the total content of the protective layer, and a content of the curing agent may be about 5 wt % to about 20 wt % with respect to the total content of the protective layer.

### BRIEF DESCRIPTION OF THE DRAWINGS

The above and other features and advantages of illustrative embodiments of the disclosure will be more apparent from the following description taken in conjunction with the accompanying drawings in which:

FIG. 1 is a schematic plan view of an embodiment of an electronic device;

FIG. 2 is a perspective view illustrating an embodiment of a display device included in an electronic device;

FIG. 3 is a cross-sectional view of the display device of FIG. 2 viewed from a lateral side;

FIG. 4A shows test results evaluating the strength of a protective layer disposed on a surface of a substrate;

FIG. 4B shows test results evaluating a contact angle according to the content of a material included in the protective layer disposed on the surface of the substrate;

FIG. 4C shows test results evaluating the strength of the protective layer according to the content of a material included in the protective layer disposed on the surface of the substrate;

FIG. 5 is a plan view illustrating an embodiment of a display layer of a display device;

FIG. 6 is an enlarged cross-sectional view of VI of FIG. 3;

FIGS. 7A to 7D are schematic cross-sectional views illustrating an embodiment of a method of manufacturing a display device;

FIG. 8 is a block diagram of an embodiment of an electronic device; and

FIG. 9 is a schematic diagram of various embodiments of an electronic device.

### DETAILED DESCRIPTION

As the disclosure allows for various changes and numerous embodiments, particular embodiments will be illustrated in the drawings and described in detail in the written description. The effects and features of the disclosure, and ways to achieve them will become apparent by referring to embodiments that will be described later in detail with reference to the drawings. However, the disclosure is not limited to the following embodiments but may be embodied in various forms.

It will be understood that although the terms “first,” “second,” etc. may be used herein to describe various elements, these elements should not be limited by these terms. These terms are only used to distinguish one element from another.

Singular expressions, unless defined otherwise in contexts, include plural expressions.

In the embodiments below, it will be further understood that the terms “comprise” and/or “have” used herein specify the presence of stated features or elements, but do not preclude the presence or addition of one or more other features or elements.

In the embodiments below, when a part such as a unit, region, or element is described as being disposed above or on another part, this includes not only the case where the part is directly above the other part, but also the case where another unit, region, element, etc. is there between.

In the embodiments below, terms such as “connect” or “combine” do not necessarily imply a direct and/or fixed connection or combination of two members, unless the context clearly indicates otherwise, and do not exclude the presence of another member between the two members.

Also, in the drawings, for convenience of description, sizes of elements may be exaggerated or contracted. For example, the size and/or thickness of each element shown in the drawings are arbitrarily shown for convenience of description, and therefore the disclosure is not necessarily limited to the drawings.

In the following embodiments, when various elements such as layers, films, regions, and plates are said to be “on” other elements, this includes not only cases where they are “directly on” other elements, but also cases where other elements are therebetween. In some embodiments, for convenience of description, the sizes of elements in the drawings may be exaggerated or reduced. For example, as sizes and thicknesses of elements in the drawings are arbitrarily illustrated for convenience of description, the disclosure is not limited thereto.

In the following embodiments, the x-axis, y-axis, and z-axis are not limited to three axes on an orthogonal coordinate system, and may be interpreted in a broad sense that includes them. For example, the x-axis, y-axis, and z-axis may be orthogonal to each other, but they may also refer to different directions that are not orthogonal to each other.

In the embodiments below, a scan driver, a scan signal, a scan control signal, a scan line, and a scan control line may also be referred to as a gate driver, a gate signal, a gate control signal, a gate line, and a gate control line, respectively.

In the embodiments below, when “about” is used in connection with a numerical value, it is intended to include a tolerance of ±10% around the numerical value mentioned.

Hereinafter, preferred embodiments of the disclosure will be described in detail with reference to the attached drawings. When describing with reference to the drawings, identical or corresponding elements are given the same drawing reference numerals and redundant descriptions thereof will be omitted.

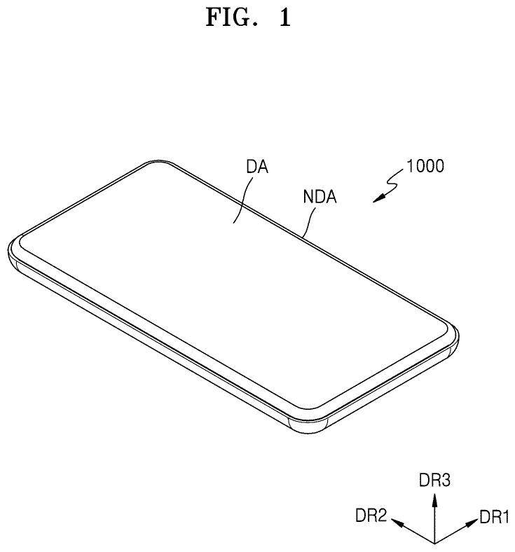

FIG. 1 is a schematic plan view of an embodiment of an electronic device.

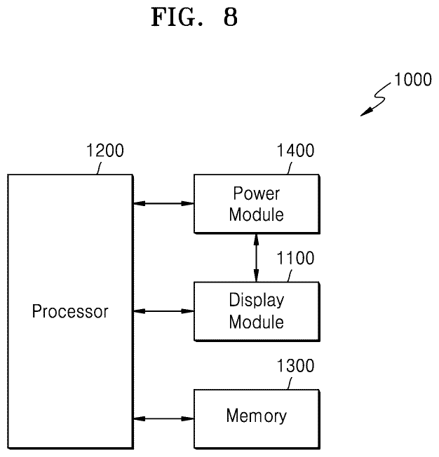

Referring to FIG. 1, an electronic device 1000 may refer to any electronic device that provides a display screen. In an embodiment, the electronic device 1000 may include a television, a laptop, a monitor, a billboard, an Internet of Things, a mobile phone, a smart phone, a tablet personal computer (“PC”), an electronic watch, a smart watch, a watch phone, a head-mounted display, a mobile communication terminal, an electronic notebook, an electronic book, a portable multimedia player (“PMP”), a navigation system, a game console, a digital camera, a camcorder, etc., which provide a display screen, for example. Below, a smart phone is provided in an embodiment of the electronic device 1000, but the disclosure is not limited thereto. Additional details regarding the electronic device 1000 are described again with reference to FIG. 8.

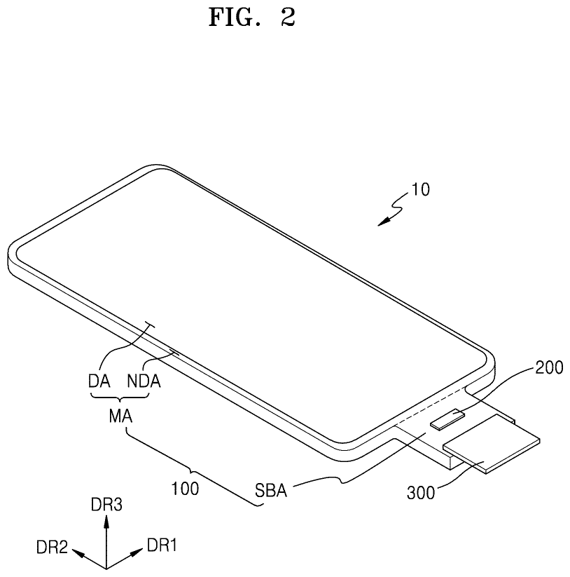

The electronic device 1000 may include a display device (10 of FIG. 2) providing a display screen as a module. In embodiments, the display device may include inorganic light-emitting diode displays, organic light-emitting displays, quantum dot light-emitting displays, plasma displays, and field emission displays. Below, in an embodiment of the display device, an organic light-emitting diode is used, but is not limited thereto, and when the same technical idea is applicable, this may be applied to other display devices.

The shape of the electronic device 1000 may be modified in various manners. In an embodiment, the electronic device 1000 may have a shape such as a horizontally long rectangle, a vertically long rectangle, a square, a rectangle with rounded corners (vertices), other polygons, a circle, etc., for example. The shape of a display area DA of the electronic device 1000 may also be similar to the overall shape of the electronic device 1000. In FIG. 1, the electronic device 1000 having a long quadrangular shape, e.g., long rectangular shape, in a second direction DR2 is illustrated.

The electronic device 1000 may include the display area DA and a non-display area NDA. The display area DA is an area where an image may be displayed, and the non-display area NDA is an area where the screen cannot be displayed. The display area DA may also be also referred to as an active area, and the non-display area NDA may also be also referred to as an inactive area. The display area DA may generally occupy a center portion of the electronic device 1000.

FIG. 2 is a perspective view illustrating an embodiment of a display device included in an electronic device.

Referring to FIG. 2, the electronic device 1000 in an embodiment may include the display device 10. The display device 10 may provide an image to be displayed on the electronic device 1000. The display device 10 may have a flat shape similar to the electronic device 1000. In an embodiment, the display device 10 may have a shape similar to a rectangle having a short side in a first direction DR1 and a long side in the second direction DR2, for example. A corner where the short side in the first direction DR1 and the long side in the second direction DR2 meet each other may be formed to have a rounded curvature, but is not limited thereto and may also be formed at a right angle. The flat shape of the display device 10 is not limited to a square, and may be formed similarly to other polygons, circles, or ovals.

The display device 10 may include a display panel 100, a display driving portion 200, and a circuit board 300.

The display panel 100 may include a main area MA and a sub-area SBA.

The main area MA may include the display area DA including pixels displaying an image and the non-display area NDA disposed around the display area DA. The display area DA may emit light from a plurality of emission areas or a plurality of opening areas. In an embodiment, the display panel 100 may include a pixel circuit including switching elements, a pixel-defining film defining an emission area or an opening area, and a self-light-emitting element, for example.

In an embodiment, the self-light-emitting element may include, but is not limited to, at least one of an organic light-emitting diode (“OLED”) including an organic light-emitting layer, a quantum dot light-emitting diode (“LED”) including a quantum dot light-emitting layer, an inorganic LED including an inorganic semiconductor, and a micro light-emitting diode (micro LED), for example.

The non-display area NDA may be an area outside the display area DA. The non-display area NDA may be defined as an edge area of the main area MA of the display panel 100. The non-display area NDA may include a scan driver (not shown) configured to supply scan signals to scan lines, and fan out lines (not shown) that connect the display driving portion 200 to the display area DA.

The sub-area SBA may be an area extending from one side of the main area MA. The sub-area SBA may include a flexible material that is bendable, foldable, or rollable. In an embodiment, when the sub-area SBA is bendable, the sub-area SBA may overlap the main area MA in a thickness direction (third direction DR3), for example. The sub-area SBA may include the display driving portion 200 and a pad portion connected to the circuit board 300. In another embodiment, the sub-area SBA may be omitted, and the display driving portion 200 and the pad portion may be arranged in the non-display area NDA.

The display driving portion 200 may output signals and voltages for driving the display panel 100. The display driving portion 200 may supply data voltages to data lines. In an embodiment, the display driving portion 200 may include a data driver, and the data driver may supply data voltages to data lines, for example. The display driving portion 200 may supply power voltage to a power line and supply a scan control signal to the scan driver. The display driving portion 200 may be formed as an integrated circuit (“IC”) and may be disposed (e.g., mounted) on the display panel 100 using a chip on glass (“COG”) method, a chip on plastic (“COP”) method, or an ultrasonic bonding method. In an embodiment, the display driving portion 200 may be disposed in the sub-area SBA and may overlap the main area MA in the thickness direction by bending of the sub-area SBA, for example. In another embodiment, the display driving portion 200 may be disposed (e.g., mounted) on the circuit board 300.

The circuit board 300 may be attached to the pad portion of the display panel 100 by an anisotropic conductive film (“ACF”). Lead lines of the circuit board 300 may be electrically connected to the pad portion of the display panel 100. The circuit board 300 may include a flexible printed circuit board, a printed circuit board, or a flexible film such as a chip on film.

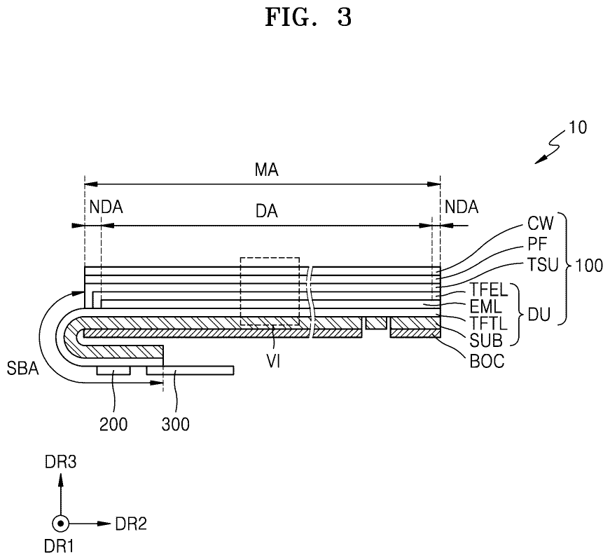

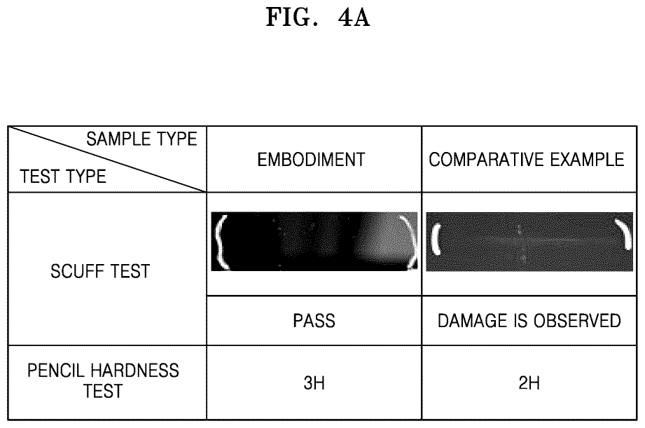

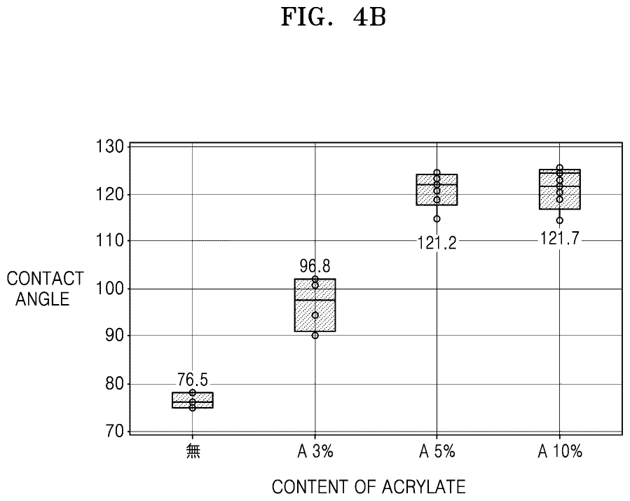

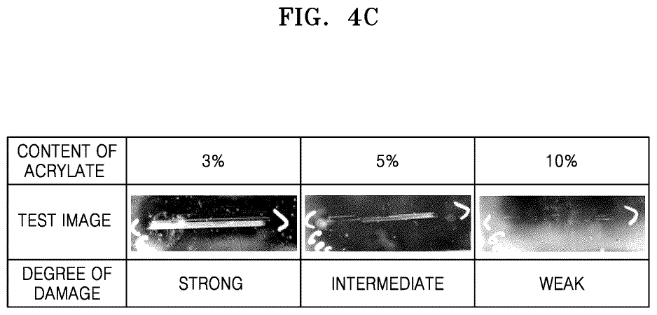

FIG. 3 is a cross-sectional view of the display device 10 of FIG. 2 viewed from a lateral side. FIG. 4A shows test results evaluating the strength of a protective layer disposed on a surface (hereinafter also referred to as a second surface) of a substrate. FIG. 4B shows test results evaluating a contact angle according to the content of a material included in the protective layer disposed on the surface of the substrate. FIG. 4C shows test results evaluating the strength of the protective layer according to the content of a material included in the protective layer disposed on the surface of the substrate.

Referring to FIG. 3, the display panel 100 may include a protective layer BOC, a display layer DU, a touch sensing layer TSU, a polarization film PF, and a cover window CW in the third direction DR3. The display layer DU may include a substrate SUB, a thin-film transistor layer TFTL, a light-emitting element layer EML, and an encapsulation layer TFEL in the third direction DR3. The protective layer BOC is disposed on the second surface (e.g., lower surface) of the substrate SUB, opposite to a surface (e.g., upper surface, hereinafter also referred to as a first surface) on which the thin-film transistor layer TFTL is disposed.

The substrate SUB may include a base substrate or a base member. In an embodiment, the substrate SUB may include, but is not limited to, a glass material, for example. In other embodiments, the substrate SUB may include a polymer resin such as PI or a metallic material. Below, an example is given in which the substrate SUB includes glass.

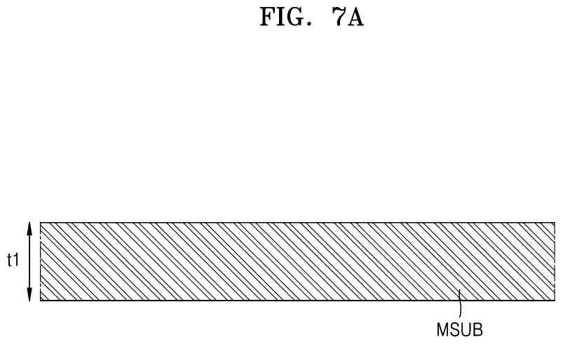

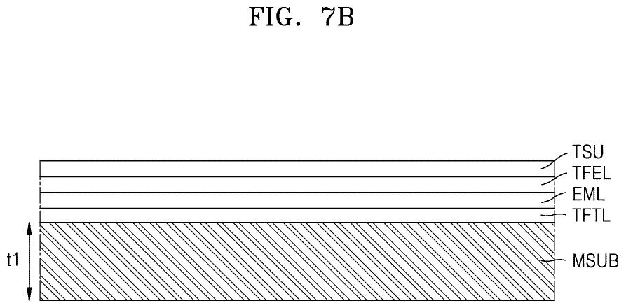

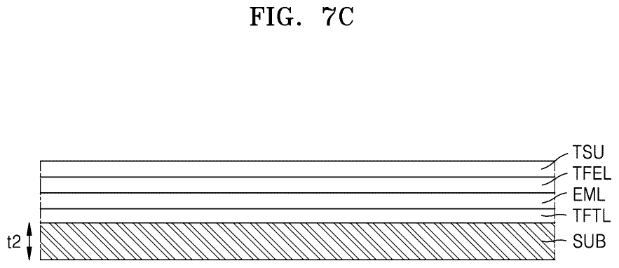

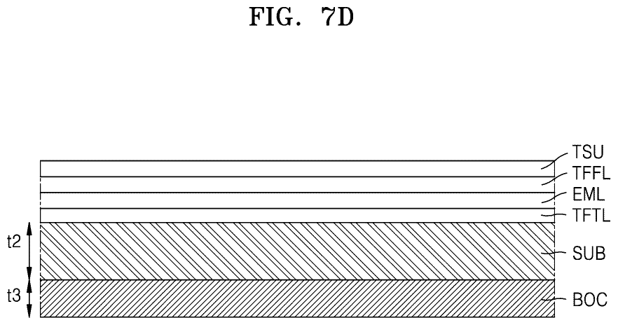

The substrate SUB may have a thickness in a range of about 20 micrometers (μm) to about 50 micrometers for manufacturing an ultra-thin (“UT”) display panel 100. The thickness of the substrate SUB may be about 30 micrometers. The substrate SUB may have a thickness that is reduced, by etching, from that of a mother substrate (MSUB in FIG. 7A) having a thickness exceeding about 50 micrometers.

The substrate SUB includes the first surface on which the thin-film transistor layer TFTL is disposed and the second surface opposite to the first surface. The second surface of the substrate SUB may be a surface on which etching is performed to reduce the thickness thereof. The protective layer (also referred as a black overcoat) BOC may be disposed on the second surface of the substrate SUB to improve the strength of the display panel 100, solve light leakage problems occurring in the display panel 100, and prevent static electricity occurring during module processes.

The protective layer BOC may improve the strength of the substrate SUB and support the display panel 100. The protective layer BOC may be disposed directly on the second surface of the etched substrate SUB. The protective layer BOC may be formed on the second surface, etched surface of the substrate SUB by a coating method without any intervening layers such as an adhesive layer.

The protective layer BOC may be provided to overlap at least the main area MA of the display panel 100. Optionally, the protective layer BOC may not be provided in the sub-area SBA of the display panel 100, thereby facilitating bending of the sub-area SBA. However, the disclosure is not limited thereto, and the protective layer BOC may be provided on the entirety of the second surface of the substrate SUB so as to overlap the sub-area SBA in addition to the main area MA of the display panel 100.

A thickness of the protective layer BOC may be in a range of about 10 micrometers to about 30 micrometers. The thickness of the protective layer BOC may be in a range of about 10 micrometers to about 20 micrometers. When the thickness of the protective layer BOC satisfies the above numerical range, the display device 10 having a strength that supports plurality of layers on the substrate SUB may be manufactured without attaching a separate cover panel (cover panel) to the second surface of the substrate SUB.

The protective layer BOC may remain intact in a scuff test. In other words, the protective layer BOC may be rated as scratch-free in the scuff test. In some embodiments, the protective layer BOC may have a pencil hardness of approximately 3H or higher. The substrate SUB may have a thickness reduced by etching, which may reduce the strength of the display panel 100. The protective layer BOC is not damaged in a scuff test and has a pencil hardness of about 3H or higher, thereby improving the strength of the display panel 100, protecting the etched substrate SUB, and preventing damage such as scratches that occur during the processes. In some embodiments, as the protective layer BOC is not damaged in a scuff test and the pencil hardness of the protective layer BOC is 3H or higher, the strength of the display panel 100 may be improved without attaching an additional cover panel to the second surface of the substrate SUB, and the display device 10 that is relatively thin may be implemented.

In the scuff test, Scuff evaluation was performed by measuring the scratch level of the protective layer BOC by performing ten reciprocating movements on a surface of a sample of the protective layer BOC in the embodiment, while placing a 1.5 kilograms (kg) weight on No. 0000 steel wool. In some embodiments, for comparison, a scuff test was performed on a comparative example in which a conductive black paste was applied to the second surface of the substrate SUB with a thickness of about 15 micrometers. As shown in FIG. 4A, which is an image showing the surface after performing a scuff test on each of the protective layer BOC in an embodiment and the comparative example, multiple scratches were observed in a horizontal direction in the case of the comparative example, but no scratches were observed in the embodiment.

The pencil hardness was measured on the surface of the sample of the protective layer BOC in the embodiment at a load of about 1 kg, a contact angle of the pencil of about 45 degrees, and a moving speed of the pencil of about 1 millimeter pe second (mm/sec). In some embodiments, for comparison, a pencil hardness test was performed on a comparative example in which a conductive black paste was applied to the second surface of the substrate SUB with a thickness of approximately 15 micrometers. As shown in FIG. 4A, which is a result of the pencil hardness test performed on each of the protective layer BOC in the embodiment and the comparative example, it may be confirmed that the pencil hardness of the comparative example is 2H, but the pencil hardness of the embodiment is at least 3H.

The surface resistivity of the protective layer BOC may be less than about 10¹² ohm per square (Ω/sq). In some embodiments, the surface resistance of the protective layer BOC may be less than or equal to about 10¹⁰ ohm per square (Ω/sq). The surface resistance of the protective layer BOC was measured using a surface resistance meter (TREK 152-1, TREK). When the surface resistance of the protective layer BOC satisfies the numerical range described above, foreign substances may be prevented from flowing into the display device 10 due to static electricity generated during the manufacturing process or use of the display device 10.

The protective layer BOC may include at least a first compound including a polyhedral oligomeric silsesquioxane (“POSS”) compound, a second compound including a resin, and a third compound including a conductive carbon-based compound.

In some embodiments, the first compound and the second compound may be used together to improve the mechanical strength of the substrate SUB, the thickness of which is reduced after etching. The second compound may further include one or more materials selected from a polyurethane resin, an acrylate resin, or an epoxy resin.

The third compound may include one or more conductive carbon compounds including at least one of carbon black, graphite, graphene, carbon nanotubes (“CNTs”), and conductive organic black. The third compound provides an antistatic function by lowering the surface resistance of the protective layer BOC due to the conductivity thereof. In some embodiments, the third compound may prevent light leakage of the display panel 100 without attaching an additional cover panel to the substrate SUB and may adjust a color tone of the display panel 100.

The conductive carbon-based compound is evenly dispersed within the protective layer BOC without clumping. For this purpose, the conductive carbon-based compound may be surface-treated. In an embodiment, the constituent particles of the conductive carbon-based compound may be surface-treated particles (e.g., carbon particles), for example. In an embodiment, the conductive carbon-based compound may be that obtained through chemical modification of adding a functional group (e.g., a carboxyl group, a hydroxyl group, or an amine group) to the surface of carbon particles or physical modification performed on the surface of carbon particles through plasma treatment or ultraviolet irradiation or may have a surface energy lowered by adsorbing a surfactant to the surface of carbon particles, or may have enhanced dispersion stability enhanced by adsorbing or chemically bonding a polymer to the surface of carbon particles, for example.

A sum of a content of the first compound and a content of the second compound may be about 45 wt % to about 75 wt % with respect to a total content of the protective layer BOC. That is, a percentage of a sum of a weight of the first compound and a weight of the second compound relative to a total weight of the protective layer BOC may be about 45 wt % to about 75 wt %. In some embodiments, a content of the third compound may be about 10 wt % to about 20 wt % with respect to the total content of the protective layer BOC. When the content of the compounds satisfies the numerical range described above, relatively high strength satisfying the desired specifications may be maintained without attaching a separate cover panel to the second surface of the substrate SUB, and at the same time, surface resistance within a range where defects may be significantly reduced may be secured. In some embodiments, color adjustment and prevention of light leakage of the display panel 100 may also be achieved when the content of the third compound satisfies the numerical range described above.

The protective layer BOC may further include a slip agent in addition to the first compound, the second compound, and the third compound. The slip agent may reduce the surface friction of the protective layer BOC, increase the surface contact angle of the protective layer BOC, provide scratch resistance, and improve surface strength. The slip agent may include one or more substances selected from fluorine-based compounds or silicone-based compounds. In an embodiment, the fluorine compounds may include or consist of polytetrafluoroethylene (“PTFE”, Teflon®), fluorinated alkyl polymer, fluorinated acrylate, and fluorinated polyurethane, for example. The silicone-based compound that may be selected may include polydimethylsiloxane (“PDMS”), silicone resin, silicone-polyether block copolymer, and silicone modified acrylate. However, the embodiments of the disclosure are not limited to these.

A content of the slip agent may be about 15 wt % or less with respect to the total content of the protective layer BOC. The content of the slip agent may be in a range of about 10 wt % to about 15 wt % with respect to the total content of the protective layer BOC. When the content of the slip agent satisfies the numerical range described above, a balance may be maintained between surface properties related to friction reduction and durability. When the content of the slip agent is outside the numerical range described above, it is difficult to achieve mechanical strength for scratch prevention, and problems may also arise in the stability of the manufacturing process.

The protective layer BOC may control the content of the second compound that implements improved contact angle and relatively high strength by including the slip agent. When the slip agent is in a range of about 10 wt % to about 15 wt % with respect to the total content of the protective layer BOC, the content of the second compound (e.g., acrylate) may be at least about 10 wt % with respect to the total content of the protective layer BOC. As shown in FIG. 4B, when the slip agent is included in the protective layer BOC, it may be confirmed that the contact angle of the protective layer BOC according to the content of acrylate, which is a type of the second compound, is rapidly improved even when the acrylate is included in an amount of only about 5 wt % or more with respect to the total content of the protective layer BOC. In some embodiments, as shown in FIG. 4C, when the slip agent is included in the protective layer BOC, it is shown in scuff test results according to the content of acrylate, which is a type of the second compound, that almost no damage is observed when acrylate is included in an amount of about 10 wt % or more with respect to the total content of the protective layer BOC. Accordingly, according to the results of FIGS. 4B and 4C, the acrylate content that realizes improved contact angle and relatively high strength may be confirmed to be about 10 wt % or more with respect to the total content of the protective layer BOC.

The protective layer BOC may further include a curing agent in addition to the first compound, the second compound, and the third compound. The curing agent may include at least one of a photocuring agent and a thermal curing agent. In some embodiments, the curing agent may be a photocuring agent that is cured by ultraviolet (“UV”) rays. The protective layer BOC may be cured by a curing agent to have improved mechanical strength and durability.

A content of the curing agent may be within about 20 wt % of the total content of the protective layer BOC. The content of the curing agent may be within about 15 wt % with respect to the total content of the protective layer BOC. More preferably, the content of the curing agent may be in a range of about 5 wt % to about 20 wt % with respect to the total content of the protective layer BOC. When the content of the curing agent satisfies the numerical range described above, a photocuring or thermal curing reaction may proceed effectively, thereby maximizing the mechanical strength and durability of the protective layer BOC.

Optionally, the protective layer BOC may further include a solvent in addition to the first compound, the second compound, and the third compound, but may not include a solvent. When the protective layer BOC includes a solvent, as the solvent, propylene glycol monomethyl ether acetate (“PGMEA”), which has excellent solubility in POSS compounds and resins and may be uniformly dissolved, may be selected, and when a solvent is included, the content of the solvent is the remainder.

Referring back to FIG. 3, the thin-film transistor layer TFTL may be disposed on the substrate SUB. The thin-film transistor layer TFTL may include a plurality of thin-film transistors that constitute a pixel circuit of pixels. The thin-film transistor layer TFTL may further include scan lines, data lines, power lines, scan control lines, fan out lines connecting the display driving portion 200 to the data lines, and lead lines connecting the display driving portion 200 to the pad portion. Each of the thin-film transistors may include a semiconductor region, a source electrode, a drain electrode, and a gate electrode.

The thin-film transistor layer TFTL may be disposed in the display area DA, the non-display area NDA, and the sub-area SBA. The thin-film transistors, the scan lines, the data lines, and the power lines of each pixel of the thin-film transistor layer TFTL may be arranged in the display area DA. The scan control lines and the fan out lines of the thin-film transistor layer TFTL may be arranged in the non-display area NDA. The lead lines of the thin-film transistor layer TFTL may be arranged in the sub-area SBA.

The light-emitting element layer EML may be disposed on the thin-film transistor layer TFTL. The light-emitting element layer EML may include a plurality of light-emitting elements that emit light, include a pixel electrode, a common electrode, and an emission layer, and a pixel-defining film that defines emission areas. The plurality of light-emitting elements of the light-emitting element layer EML may be arranged in the display area DA.

In an embodiment, an emission layer may include an organic light-emitting layer including an organic material. The emission layer may include a hole transporting layer, an organic light-emitting layer, and an electron transporting layer. When the pixel electrode receives a voltage through the thin-film transistors of the thin-film transistor layer TFTL and the common electrode receives a cathode voltage, holes and electrons may move to the organic light-emitting layer through the hole transport layer and the electron transport layer, respectively, and combine with each other in the organic light-emitting layer to emit light.

In other embodiments, the light-emitting element may include a quantum dot light-emitting diode including a quantum dot light-emitting layer, an inorganic light-emitting diode including an inorganic semiconductor, or a micro light-emitting diode.

The touch sensing layer TSU may be disposed on the encapsulation layer TFEL. The touch sensing layer TSU may include a plurality of touch electrodes for detecting a user's touch in a capacitive manner, and touch lines connecting the plurality of touch electrodes and a touch driver (not shown). In an embodiment, the touch sensing layer TSU may sense a user's touch in a mutual capacitance or self-capacitance manner, for example.

The polarization film PF may be disposed on the touch sensing layer TSU. The polarization film PF may be disposed on the display panel 100 to reduce external light reflection. The polarization film PF may include a first base member, a linear polarization plate, a phase retardation film such as a λ/4 plate (quarter-wave plate), and a second base member. The first base member, the phase retardation film, the linear polarization plate, and the second base member of the polarization film PF may be sequentially laminated on the touch sensing layer TSU.

The cover window CW may be disposed on the polarization film PF. The cover window CW may be attached to the polarization film PF by a transparent adhesive material such as an optically clear adhesive (“OCA”) film.

In another embodiment, a color filter layer (not shown) may be disposed on the touch sensing layer TSU instead of the polarization film PF and the cover window CW. The color filter layer may include a plurality of color filters respectively corresponding to a plurality of emission areas. Each color filter may selectively transmit light of a predetermined wavelength and block or absorb light of other wavelengths. The color filter layer may absorb some of the light coming from the outside of the display device 10 to reduce reflected light due to external light. Thus, the color filter layer may prevent color distortion due to external light reflection.

As the color filter layer is disposed directly on the touch sensing layer TSU, a separate substrate for the color filter layer may not be desired in the display device 10. Therefore, the thickness of the display device 10 may be relatively small.

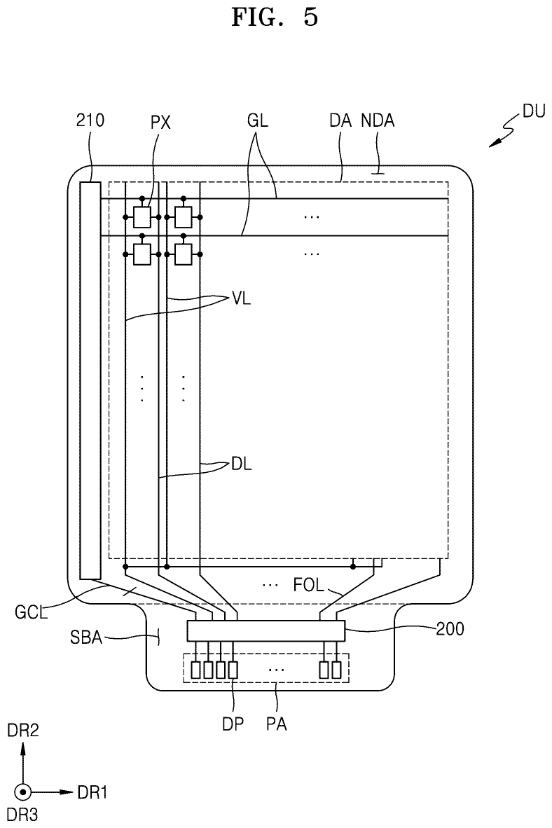

FIG. 5 is a plan view illustrating an embodiment of a display layer of a display device.

Referring to FIG. 5, the display layer DU may include the display area DA and the non-display area NDA.

The display area DA may be disposed in a center of the display panel 100. A plurality of pixels PX, a plurality of scan lines GL, a plurality of data lines DL, and a plurality of power lines VL may be arranged in the display area DA. Each of the plurality of pixels PX may be defined as a smallest unit that emits light.

The plurality of scan lines GL may supply scan signals received from a scan driver 210 to the plurality of pixels PX. The plurality of scan lines GL may extend in the first direction DR1 and be spaced apart from each other in the second direction DR2 intersecting the first direction DR1.

The plurality of data lines DL may supply data voltages received from the display driving portion 200 or a data driver within the display driving portion 200, to the plurality of pixels PX. The plurality of data lines DL may extend in the second direction DR2 and be spaced apart from each other in the first direction DR1.

The plurality of power lines VL may supply a power voltage received from the display driving portion 200, to the plurality of pixels PX. In some embodiments, the power voltage may be at least one of a driving voltage (or first voltage), an initialization voltage, a reference voltage, and a low-potential voltage (or second voltage having a voltage level less than that of the first voltage). The plurality of power lines VL may extend in the second direction DR2 and be spaced apart from each other in the first direction DR1.

The non-display area NDA may surround the display area DA. The scan driver 210, fan out lines FOL, and scan control lines GCL may be arranged in the non-display area NDA. The scan driver 210 may generate a plurality of scan signals based on a scan control signal and sequentially supply the plurality of scan signals to the plurality of scan lines GL in a set order.

The sub-area SBA may include the display driving portion 200 and a pad area PA.

The display driving portion 200 may output signals and voltages for driving the display panel 100 to the fan out lines FOL. The data driver included in the display driving portion 200 may supply a data voltage to the data line DL through the fan out lines FOL. The data voltage may be supplied to the plurality of pixels PX, and control the brightness of the plurality of pixels PX. The display driving portion 200 may supply a scan control signal to the scan driver 210 through the scan control line GCL.

The pad area PA may include a plurality of display pad portions DP. The plurality of display pad portions DP may be connected to a graphics system through the circuit board 300. The plurality of display pad portions DP may be connected to the circuit board 300 to receive digital video data and supply the digital video data to the display driving portion 200.

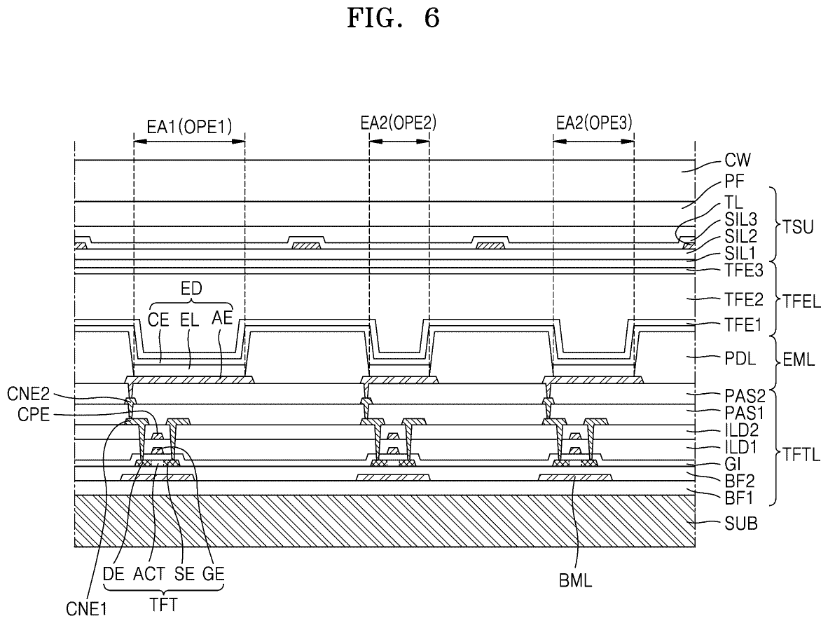

FIG. 6 is an enlarged cross-sectional view of VI of FIG. 3.

Referring to FIG. 6, the display panel 100 of the display device 10 may include the display layer DU, the touch sensing layer TSU, the polarization film PF, and the cover window CW. The display layer DU may include the substrate SUB, the thin-film transistor layer TFTL, the light-emitting element layer EML, and the encapsulation layer TFEL. The display panel 100 may include the polarization film PF and the cover window CW disposed on the touch sensing layer TSU. Below, each component of the cross-sectional view is described in the order of the manufacturing process steps of the display device.

On the first surface of the substrate SUB, the light-emitting element layer EML that displays an image and the thin-film transistor layer TFTL that drives the light-emitting element layer EML are arranged.

The thin-film transistor layer TFTL may include a first buffer layer BF1, a bottom metal layer BML, a second buffer layer BF2, the thin-film transistor TFT, a gate insulating layer GI, a first inter-insulating layer ILD1, a capacitor electrode CPE, a second inter-insulating layer ILD2, a first connection electrode CNE1, a first passivation layer PAS1, a second connection electrode CNE2, and a second passivation layer PAS2.

The first buffer layer BF1 may be disposed on the first surface of the substrate SUB. The first buffer layer BF1 may include an inorganic film capable of preventing penetration of air or moisture. In an embodiment, the first buffer layer BF1 may include a plurality of alternately laminated inorganic films, for example.

The bottom metal layer BML may be disposed on the first buffer layer BF1. In an embodiment, the bottom metal layer BML may be formed as a single layer or a plurality of layers including one or more of molybdenum (Mo), aluminum (Al), chromium (Cr), gold (Au), titanium (Ti), nickel (Ni), neodymium (Nd), and copper (Cu), or any alloys thereof, for example.

The second buffer layer BF2 may cover the first buffer layer BF1 and the bottom metal layer BML. The second buffer layer BF2 may include an inorganic film capable of preventing penetration of air or moisture. In an embodiment, the second buffer layer BF2 may include a plurality of alternately laminated inorganic films, for example.

The thin-film transistor TFT is formed within a pixel on the second buffer layer BF2. The thin-film transistor TFT may be disposed on the second buffer layer BF2 and form a pixel circuit of each of a plurality of pixels. In an embodiment, the thin-film transistor TFT may include a driving transistor or a switching transistor in a pixel circuit, for example. The thin-film transistor TFT may include a semiconductor layer ACT, a source electrode SE, a drain electrode DE, and a gate electrode GE.

The semiconductor layer ACT may be disposed on the second buffer layer BF2. The semiconductor layer ACT may overlap the bottom metal layer BML and the gate electrode GE in the thickness direction, and may be insulated from the gate electrode GE by the gate insulating layer GI.

The gate electrode GE may be disposed on the gate insulating layer GI. The gate electrode GE may overlap the semiconductor layer ACT with the gate insulating layer GI therebetween.

The gate insulating layer GI may be disposed on the semiconductor layer ACT. In an embodiment, the gate insulating layer GI may cover the semiconductor layer ACT and the second buffer layer BF2, and insulate the semiconductor layer ACT from the gate electrode GE, for example. A contact hole through which the first connection electrode CNE1 passes may be defined in the gate insulating layer GI.

The first inter-insulating layer ILD1 may cover the gate electrode GE and the gate insulating layer GI. A contact hole through which the first connection electrode CNE1 passes may be defined in the first inter-insulating layer ILD1. The contact hole of the first inter-insulating layer ILD1 may be extended to the contact hole of the gate insulating layer GI and a contact hole of the second inter-insulating layer ILD2.

The capacitor electrode CPE may be disposed on the first inter-insulating layer ILD1. The capacitor electrode CPE may overlap the gate electrode GE in the thickness direction. The capacitor electrode CPE and the gate electrode GE may form electrostatic capacitance.

The second inter-insulating layer ILD2 may cover the capacitor electrode CPE and the first inter-insulating layer ILD1. The contact hole through which the first connection electrode CNE1 passes may be defined in the second inter-insulating layer ILD2. The contact hole of the second inter-insulating layer ILD2 may be extended to the contact hole of the first inter-insulating layer ILD1 and the contact hole of the gate insulating layer GI.

The first connection electrode CNE1 may be disposed on the second inter-insulating layer ILD2. The first connection electrode CNE1 may electrically connect the drain electrode DE of the thin-film transistor TFT to the second connection electrode CNE2. The first connection electrode CNE1 may be inserted into the contact holes defined in the second inter-insulating layer ILD2, the first inter-insulating layer ILD1, and the gate insulating layer GI to contact the drain electrode DE of the thin-film transistor TFT.

The first passivation layer PAS1 may cover the first connection electrode CNE1 and the second inter-insulating layer ILD2. The first passivation layer PAS1 may be formed on the thin-film transistor TFT to protect the thin-film transistor TFT. A contact hole through which the second connection electrode CNE2 passes may be defined in the first passivation layer PAS1. The first passivation layer PAS1 may include an organic material such as acrylic, benzocyclobutene (“BCB”), or hexamethyldisiloxane (“HMDSO”), for example.

The second connection electrode CNE2 may be disposed on the first passivation layer PAS1. The second connection electrode CNE2 may electrically connect the first connection electrode CNE1 to a pixel electrode AE of a light-emitting element ED. The second connection electrode CNE2 may be inserted into the contact hole defined in the first passivation layer PAS1 and contact the first connection electrode CNE1.

The second passivation layer PAS2 may be formed on the second connection electrode CNE2 and the first passivation layer PAS1 to cover the first passivation layer PAS1. A contact hole through which the pixel electrode AE of the light-emitting element ED passes may be defined in the second passivation layer PAS2. The second passivation layer PAS2 may include a same organic material as that of the first passivation layer PAS1, such as acrylic, BCB, or HMDSO. An upper surface of the second passivation layer PAS2 may be flat.

The light-emitting element layer EML may be disposed on the thin-film transistor layer TFTL. The light-emitting element layer EML may include the light-emitting element ED and a pixel-defining layer PDL. The light-emitting element ED may include the pixel electrode AE, an emission layer EL, and a common electrode CE.

The pixel electrode AE may be disposed on the second passivation layer PAS2. The pixel electrode AE may be disposed to overlap any one of openings OPE1, OPE2, OPE3 of the pixel-defining layer PDL. The pixel electrode AE may be electrically connected to the drain electrode DE of the thin-film transistor TFT through the first and second connection electrodes CNE1, CNE2.

The pixel-defining layer PDL is formed on the pixel electrode AE. The plurality of openings OPE1, OPE2, OPE3 may be defined in the pixel-defining layer PDL disposed on the second passivation layer PAS2 and a portion of the pixel electrode AE. A first opening OPE1, a second opening OPE2, and a third opening OPE3 may be defined in the pixel-defining layer PDL, and each of the first to third openings OPE1, OPE2, OPE3 may expose a portion of the pixel electrode AE. As described above, each of the first to third openings OPE1, OPE2, OPE3 of the pixel-defining layer PDL may define first to third emission areas EA1, EA2, EA3, respectively, and their areas or sizes may be different from each other. The pixel-defining layer PDL may separate and insulate pixel electrodes AE of each of a plurality of light-emitting elements ED. The pixel-defining layer PDL may include a light-absorbing material to prevent light reflection. In an embodiment, the pixel-defining layer PDL may include a polyimide (“PI”)-based binder and a combination of red, green, and blue pigments, for example. In an alternative embodiment, the pixel-defining layer PDL may include a combination of a cardo-based binder resin and a lactam black pigment and a blue pigment. In an alternative embodiment, the pixel-defining layer PDL may include carbon black.

In some embodiments, the emission areas EA1, EA2, and EA3 may include a first emission area EA1, a second emission area EA2, and a third emission area EA3 that emit light of different colors. The first to third emission areas EA1, EA2, and EA3 may emit red, green, or blue light, respectively, and the color of the light emitted from each of the first to third emission areas EA1, EA2, and EA3 may vary depending on the type of light-emitting element disposed in the light-emitting element layer EML described below. In an embodiment, the first emission area EA1 may emit a first light of red color, the second emission area EA2 may emit a second light of green color, and the third emission area EA3 may emit a third light of blue color. However, the disclosure is not limited thereto.

In some embodiments, the display device 10 may form one pixel group by having one first emission area EA1, one second emission area EA2, and one third emission area EA3 arranged next (adjacent) to each other. A single pixel group may express white gradations by including the first to third emission areas EA1, EA2 and EA3 that emit light of different colors. However, the disclosure is not limited thereto, and the combination of the first to third emission areas EA1, EA2, and EA3 constituting one pixel group may be variously modified depending on the arrangement of the first to third emission areas EA1, EA2 and EA3 and the color of the light they emit.

The emission layer EL may be disposed on the pixel electrode AE. The emission layer EL may be formed to correspond to emission areas defined by openings of the pixel-defining layer PDL. In an embodiment, the emission layer EL may include an organic light-emitting layer including an organic material, for example, but is not limited thereto. When the emission layer EL corresponds to an organic light-emitting layer, and when the thin-film transistor TFT applies a predetermined voltage to the pixel electrode AE of the light-emitting element ED, and the common electrode CE of the light-emitting element ED receives a common voltage or cathode voltage, holes and electrons may move to the emission layer EL through the hole transport layer and the electron transport layer, respectively, and the holes and electrons may combine with each other in the emission layer EL to emit light.

The common electrode CE may be disposed on the emission layer EL. The common electrode CE may be formed to cover an upper surface of emission layer EL. In an embodiment, the common electrode CE may be implemented as an electrode common to all pixels without being differentiated for each pixel, for example. The common electrode CE may be disposed on the emission layer EL in the first to third emission areas EA1, EA2, and EA3, and may be disposed on the pixel-defining layer PDL in an area excluding the first to third emission areas EA1, EA2, and EA3. The common electrode CE may include a transparent conductive material to improve light extraction efficiency, but is not limited thereto and may also include a semi-permeable film including a metal.

The common electrode CE may receive a common voltage, a low-level voltage, or a second voltage. When the pixel electrode AE receives a voltage corresponding to a data voltage and the common electrode CE receives a low-potential voltage, a potential difference is formed between the pixel electrode AE and the common electrode CE, causing the emission layer EL to emit light.

The encapsulation layer TFEL may be disposed on the common electrode CE and cover the plurality of light-emitting elements ED. The encapsulation layer TFEL may include at least one inorganic film to prevent oxygen or moisture from penetrating into the light-emitting element layer EML. The encapsulation layer TFEL may include at least one organic film to protect the light-emitting element layer EML from foreign substances such as dust.

In an embodiment, the encapsulation layer TFEL may include a first encapsulation layer TFE1, a second encapsulation layer TFE2, and a third encapsulation layer TFE3. The first encapsulation layer TFE1 and the third encapsulation layer TFE3 may be inorganic encapsulation layers, and the second encapsulation layer TFE2 disposed therebetween may be an organic encapsulation layer.

The touch sensing layer TSU may be disposed on the encapsulation layer TFEL. The touch sensing layer TSU may have an insulating function and an optical function. The touch sensing layer TSU may sequentially include a first touch insulation layer SIL1, a second touch insulation layer SIL2, a touch electrode TL, and a third touch insulation layer SIL3 in a direction from the encapsulation layer TFEL to the polarization film PF.

The polarization film PF may be disposed on the touch sensing layer TSU. The cover window CW may be disposed on the polarization film PF.

FIGS. 7A to 7D are schematic cross-sectional views illustrating an embodiment of a method of manufacturing a display device.

Referring to FIG. 7A, first, a mother substrate MSUB is prepared. The mother substrate MSUB may include a glass material or may include or consist of a glass material. A thickness of the mother substrate MSUB may exceed approximately 50 micrometers. In some embodiments, the thickness of the mother substrate MSUB may be greater than about 50 micrometers and less than or equal to about 1000 micrometers. The mother substrate MSUB includes a surface and an opposite surface facing the surface.

Referring to FIG. 7B, a plurality of layers are formed on one surface of the mother substrate MSUB. The plurality of layers may include the thin-film transistor layer TFTL, the light-emitting element layer EML, the encapsulation layer TFEL, and the touch sensing layer TSU from the one surface of the mother substrate MSUB. The configuration and manufacturing method of the thin-film transistor layer TFTL, the light-emitting element layer EML, the encapsulation layer TFEL, and the touch sensing layer TSU are described with reference to FIG. 6, and thus repeated description is omitted.

Although not shown, a plurality of protective films are attached on the plurality of layers. Each of the plurality of protective films may include a buffer film for protecting the plurality of layers from external impact during the process. The plurality of protective films may include a transparent material. In some embodiments, among the plurality of protective films, an outermost film may be an acid-resistant film for protecting the plurality of layers from an etching process of the mother substrate MSUB to be performed in a next operation.

Referring to FIG. 7C, a slimming process is performed to reduce the thickness of the mother substrate MSUB. By spraying an etchant on another surface of the mother substrate MSUB, the thickness of the mother substrate MSUB may be reduced. In an embodiment, the thickness of the mother substrate MSUB may be reduced from a first thickness t1 to a second thickness t2, for example. The second thickness t2 may differ by about 50 micrometers or more compared to the first thickness t1. The second thickness t2 may range from about 20 micrometers to about 50 micrometers. In some embodiments, the second thickness t2 may be about 30 micrometers. The mother substrate MSUB with a reduced thickness is also referred to as the substrate SUB. After reducing the thickness of the MSUB, the protective films may be removed.

Referring to FIG. 7D, the protective layer BOC may be formed on another surface of the etched substrate SUB. The protective layer BOC is formed by screen printing. The protective layer BOC may be formed by screen-printing a coating solution onto another surface of the substrate SUB and then curing the coating solution through UV irradiation or heat supply. The coating solution may include a first compound including a POSS compound, a second compound including a resin, and a third compound including a conductive carbon-based compound, and may further include a slip agent and/or a curing agent. Accordingly, the protective layer BOC may also include the first compound, the second compound, and the third compound described above, and may further include a slip agent and/or a curing agent. A thickness t3 of the protective layer BOC may be in a range of about 10 micrometers to about 30 micrometers. The thickness of the protective layer BOC may be in a range of about 10 micrometers to about 20 micrometers. As the configuration or specific details of the protective layer BOC have been described above, any repeated description will be omitted.

In some embodiments, although not shown, a plurality of display cells may be formed on the mother substrate MSUB. Each of the plurality of display cells may include a plurality of layers including the thin-film transistor layer TFTL, the light-emitting element layer EML, the encapsulation layer TFEL, and the touch sensing layer TSU. After etching the mother substrate MSUB, the mother substrate MSUB may be cut along the edges of the plurality of display cells to separate the plurality of display cells. In some embodiments, operations of examining the plurality of display cells and attaching the display driving portion 200 and the circuit board 300 to each of the plurality of display cells may be further included. In some embodiments, the polarization film PF and the cover window CW may be attached to the display cells to complete the display panel 100. At least one of these processes may be performed after the process of forming the protective layer BOC. However, without limitation, at least one or more of these processes may be performed prior to the process of forming the protective layer BOC.

In an embodiment, as the protective layer BOC is provided on another surface of the substrate SUB, a separate cover panel is not desired. That is, the strength desired for the display device 10 is secured by the protective layer BOC without a separate cover panel. In some embodiments, due to the protective layer BOC, the occurrence of electrostatic defects during the processes may be reduced. In some embodiments, because of the protective layer BOC, there is a light leakage prevention effect and color correction effect, and thus a separate cover panel for light leakage prevention is not desired. Therefore, in an embodiment, the process for assembling the cover panel may be omitted, thereby simplifying the process. In some embodiments, in an embodiment, the thickness of the display panel 100 may be reduced, thereby manufacturing the display device 10 that is ultra-thin.

In some embodiments, the display device in the embodiment may be applied to various electronic devices 1000. An electronic device in an embodiment includes the display device 10 described above, and may further include a module or device having additional functions in addition to the display device 10.

FIG. 8 is a block diagram of an embodiment of an electronic device.

Referring to FIG. 8, the electronic device 1000 in an embodiment may include a display module 1100, a processor 1200, a memory 1300, and a power module 1400.

The processor 1200 may include at least one of a central processing unit (“CPU”), an application processor (“AP”), a graphics processing unit (“GPU”), a communication processor (“CP”), an image signal processor (“ISP”), and a controller.

The controller may output various control signals desired for driving the display module 1100. In an embodiment, the controller may apply various signals to pixel circuits included in the thin-film transistor layer TFTL, for example. In detail, the controller may transmit a scan control signal to the scan driver 210, and causes the scan driver 210 to output scan signals to pixel circuits in response to the scan control signal. The controller may transmit a control signal to the data driver of the display driving portion 200, and the data driver may convert image data into an analog voltage (e.g., a data voltage) in response to the control signal and output data voltages to the pixel circuits.

The memory 1300 may store data information desired for the operation of the processor 1200 or display module 1100. When the processor 1200 executes an application stored in the memory 1300, an image data signal and/or an input control signal is transmitted to the display module 1100, and the display module 1100 may process the received signal and output image information through a display screen.

The power module 1400 may include a power supply module, such as a power adapter or a battery device, and a power conversion module that converts power supplied by the power supply module to generate power desired for the operation of the electronic device 1000. In an embodiment, the power module 1400 supplies power to the controller, enabling the controller to operate, for example.

At least one of the components of the electronic device 1000 described above may be included in the display device according to the above-described embodiments. In some embodiments, some of the individual modules functionally included within a module may be included within the display device, while others may be provided separately from the display device. In an embodiment, the display device may include the display module 1100, and the processor 1200, the memory 1300, and the power module 1400 may be provided in the form of other devices within the electronic device 1000 other than the display device, for example.

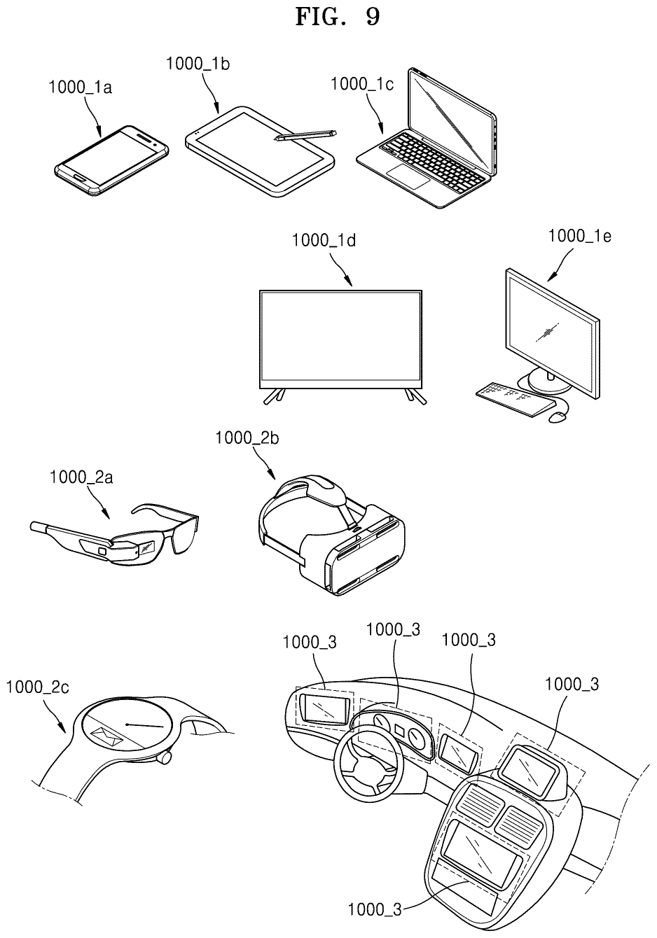

FIG. 9 is a schematic diagram of various embodiments of an electronic device.

Referring to FIG. 9, various electronic devices to which the display device in the embodiments is applied may include not only image display electronic devices such as a smart phone 1000_1a, a tablet PC 1000_1b, a laptop 1000_1c, a television (“TV”) 1000_1d, and a desk monitor 1000_1e, but also wearable electronic devices including display modules such as smart glasses 1000_2a, a head mounted display 1000_2b, and a smart watch 1000_2c, and a vehicle electronic device 1000_3 including display modules such as a center information display (“CID”) disposed on an instrument panel, a center fascia, and a dashboard of an automobile, and a room mirror display.

While illustrative embodiments have been described, it will be readily apparent to those skilled in the art that various modifications may be made therein without departing from the spirit and scope of the disclosure. Unless otherwise stated, the description of features or advantages within each embodiment should generally be considered to be applicable to other similar features or advantages of other embodiments. Accordingly, as will be apparent to one skilled in the art, features or components described in connection with a particular embodiment may be combined with features or components described in connection with other embodiments. Therefore, the foregoing should not be construed as limited to the illustrative embodiments disclosed herein, but should be understood to be intended for combination with or application to other embodiments. Therefore, the true technical protection scope of the disclosure should be determined by the technical idea of the appended claims.

The display device, the method of manufacturing the same, and the electronic device including the display device in the embodiments of the disclosure may have improved strength while being thin. The scope of the disclosure, however, is not limited by these effects.

What is claimed is:

1. A display device comprising:
a light-emitting element layer which displays an image;
a substrate having a thickness in a range of about 20 micrometers to about 50 micrometers, the substrate comprising:
a glass material;
a first surface; and
a second surface opposite to the first surface;
a thin-film transistor layer which is disposed on the first surface of the substrate and drives the light-emitting element layer; and
a protective layer disposed on the second surface of the substrate, the protective layer comprising:
a first compound comprising a polyhedral oligomeric silsesquioxane compound;
a second compound comprising a resin; and
a third compound comprising a conductive carbon-based compound.

2. The display device of claim 1, wherein the second surface of the substrate comprises a portion on which etching is performed, and the protective layer is directly disposed on the second surface of the substrate.

3. The display device of claim 1, wherein the protective layer has a pencil hardness of 3H or higher.

4. The display device of claim 1, wherein a surface resistance of the protective layer is 10¹² ohm per square (Ω/sq) or less.

5. The display device of claim 1, wherein a thickness of the protective layer is in a range of about 10 micrometers to about 30 micrometers.

6. The display device of claim 1, wherein the second compound comprises at least one material selected from a polyurethane resin, an acrylate resin, or an epoxy resin.

7. The display device of claim 1, wherein the third compound comprises at least one material selected from carbon black, graphite, graphene, carbon nanotubes, or conductive organic black.

8. The display device of claim 1, wherein a sum of a content of the first compound and a content of the second compound is about 45 wt % to about 75 wt % with respect to a total content of the protective layer, and a content of the third compound is about 10 wt % to about 20 wt % with respect to the total content of the protective layer.

9. The display device of claim 1, wherein the protective layer further comprises at least one slip agent selected from the group comprising a fluorine-based compound and a silicone-based compound.

10. The display device of claim 9, wherein a content of the slip agent is about 10 wt % to about 15 wt % with respect to the total content of the protective layer.

11. The display device of claim 1, wherein the protective layer further comprises at least one curing agent among a photocuring agent and a thermal curing agent.

12. The display device of claim 11, wherein a content of the curing agent is about 5 wt % to about 20 wt % with respect to the total content of the protective layer.

13. A method of manufacturing a display device, the method comprising:
preparing a substrate comprising a glass material;
forming, on a first surface of the substrate, a light-emitting element layer for displaying an image and a thin-film transistor layer for driving the light-emitting element layer;
etching a second surface of the substrate to form a thickness of the substrate in a range of about 20 micrometers to about 50 micrometers; and
forming a protective layer on the second surface of the etched substrate by screen printing,
wherein the protective layer comprises at least a first compound comprising a polyhedral oligomeric silsesquioxane compound, a second compound comprising a resin, and a third compound comprising a conductive carbon-based compound.

14. The method of claim 13, wherein the second compound comprises at least one material selected from a polyurethane resin, an acrylate resin, or an epoxy resin.

15. The method of claim 13, wherein the third compound comprises at least one material selected from carbon black, graphite, graphene, carbon nanotubes, or conductive organic black.

16. The method of claim 13, wherein a sum of a content of the first compound and a content of the second compound is about 45 wt % to about 75 wt % with respect to a total content of the protective layer, and a content of the third compound is about 10 wt % to about 20 wt % with respect to the total content of the protective layer.

17. The method of claim 13, wherein the protective layer further comprises at least one slip agent selected from the group comprising a fluorine-based compound and a silicone-based compound, and a content of the slip agent is about 10 wt % to about 15 wt % with respect to the total content of the protective layer.

18. The method of claim 13, wherein the protective layer further includes at least one curing agent among a photocurable agent and a thermal curable agent, and a content of the curing agent is about 5 wt % to about 20 wt % with respect to the total content of the protective layer.

19. An electronic device comprising:
a light-emitting element layer which displays an image;
a substrate having a thickness in a range of about 20 micrometers to about 50 micrometers, the substrate comprising:
a glass material;
a first surface; and
a second surface opposite to the first surface;
a thin-film transistor layer disposed on the first surface of the substrate and configured to drive the light-emitting element layer, the thin-film transistor layer including:
a pixel circuit; and
a protective layer disposed on the second surface of the substrate, the protective layer comprising:
a first compound comprising a polyhedral oligomeric silsesquioxane compound;
a second compound comprising a resin;
a third compound comprising a conductive carbon-based compound, a slip agent, and a curing agent,
a controller configured to apply a signal to the pixel circuit; and
a power module configured to supply power to the controller.

20. The electronic device of claim 19, wherein a sum of a content of the first compound and a content of the second compound is about 45 wt % to about 75 wt % with respect to a total content of the protective layer,
a content of the third compound is about 10 wt % to about 20 wt % with respect to the total content of the protective layer,
a content of the slip agent is about 10 wt % to about 15 wt % with respect to the total content of the protective layer, and
a content of the curing agent is about 5 wt % to about 20 wt % with respect to the total content of the protective layer.
